(19) United States
(12) Patent Application Publication
(10) Pub. No.: US 2025/0318238 A1
(43) Pub. Date: Oct. 9, 2025

(54) VIA-TO-BACKSIDE POWER RAIL STRUCTURE

(71) Applicant: International Business Machines Corporation, Armonk, NY (US)

(72) Inventors: HUIMEI ZHOU, Albany, NY (US); Ravikumar Ramachandran, Pleasantville, NY (US); LEI ZHUANG, Ridgefield, CT (US); Ruilong Xie, Niskayuna, NY (US); Xiaoming Yang, Clifton Park, NY (US); Eric Miller, Albany, NY (US); Mahender Kumar, Clifton Park, NY (US)

(21) Appl. No.: 18/630,554

(22) Filed: Apr. 9, 2024

(51) Int. Cl. H01L 29/417; H01L 23/528; H01L 27/088; H01L 29/06; H01L 29/423; H01L 29/775; H01L 29/786

(52) U.S. Cl. CPC H10D 64/254; H01L 23/5286; H10D 30/43; H10D 30/6735; H10D 30/6757; H10D 62/121; H10D 84/83

(57) ABSTRACT

A semiconductor device including a frontside source/drain contact/via-to-backside power rail (VBPR) structure is provided in which the overlap between the frontside source/drain contact structure of the merged frontside source/drain contact/VBPR structure and the VBPR structure of the merged frontside source/drain contact/VBPR structure is improved. The improved overlap, in turn, provides a structure having low contact resistance.

### BACKGROUND

The present application relates to semiconductor technology, and more particularly to a semiconductor device including a via-to-backside power rail (VBPR) structure for electrically connecting a backside power rail to a source/drain region of a transistor.

When forming a semiconductor structure including a plurality of complementary metal oxide semiconductor (CMOS) devices, such as integrated circuits, standard cells can be used as a base unit for designing and manufacturing the integrated circuits. The standard cell(s) can be used to form one or more functional circuits, and each standard cell can have the same footprint. Using standard cells when designing complex circuits and components reduces design and manufacture costs.

In use, each standard cell of a semiconductor structure requires power input (Vdd) and ground (Vss) connections. To power the various components thereof, each standard cell is generally coupled to a backside power rail which is electrically connected to an active layer of the standard cell to provide the power. In some instances, a plurality of backside power rails can be provided for each standard cell to respectively provide power and ground. Backside power rails are typically formed on the backside of a semiconductor substrate (or wafer). Such backside power rails are connected to a source/drain region of a field effect transistor (FET) utilizing a VBPR structure. Backside power rails are a promising solution for further semiconductor device scaling.

### SUMMARY

A semiconductor device including a merged frontside source/drain contact/VBPR structure is provided in which the overlap between the frontside source/drain contact structure of the merged frontside source/drain contact/VBPR structure and the VBPR structure of the merged frontside source/drain contact/VBPR structure is improved. The improved overlap, in turn, provides a structure having low contact resistance.

In one aspect of the present application, a semiconductor device is provided. In one embodiment of the present application, the semiconductor device includes a first transistor located on a frontside, and within a first active area, of a semiconductor device layer and including a gate structure and source/drain regions; a shallow trench isolation structure located adjacent to the first active area of the semiconductor device layer; a gate cap located on the gate structure of the first transistor; a middle-of-the-line (MOL) dielectric layer located on the gate cap and embedding the source/drain regions of the first transistor; a backside power rail located on a backside of the semiconductor device layer; and a merged frontside source/drain contact/via-to-backside power rail (VBPR) structure including a frontside source/drain contact structure merged with a VBPR structure in which the VBPR structure is in electrical contact with the backside power rail and the frontside source/drain contact structure is in electrical contact with one of the source/drain regions of the first transistor. This improves resistivity from overlay shift. In accordance with the present application, the VBPR structure has an upper portion that is embedded in, and is in contact with, the MOL dielectric layer, a middle portion that is spaced apart from each of the gate cap, the gate structure and the source/drain region of the first transistor that is in electrical contact with the frontside source/drain contact structure by a gate cut dielectric spacer, and a lower portion that is surrounded by, and in direct contact with, the shallow trench isolation structure.

### BRIEF DESCRIPTION OF THE DRAWINGS

FIG. 1 is a top down view of a device layout that can be used in the present application for forming a semiconductor device including a VBPR structure.

FIGS. 2A, 2B and 2C are cross sectional views of an exemplary structure through cut A-A, cut B-B, and cut C-C illustrated in FIG. 1, respectively, that can be employed in accordance with an embodiment of the present application, the exemplary structure including first nanosheet transistors located in a first active area of a semiconductor device layer of a substrate, and second nanosheet transistors located in a second active area of the semiconductor device layer, in which a gate cut trench structure separates each first nanosheet transistor from each second nanosheet transistor and a gate cap is located on each first nanosheet transistor and each second nanosheet transistor.

FIGS. 3A, 3B and 3C are cross sectional views of the exemplary structure shown in FIGS. 2A, 2B and 2C, respectively, after forming an additional frontside interlayer dielectric (ILD) material on a first frontside ILD layer that is located on the source/drain regions of each first nanosheet transistor and each second nanosheet transistor, and on top of the gate cap and the gate cut trench structure, in which the additional frontside ILD material and the first frontside ILD layer collectively provide a middle-of-the-line (MOL) dielectric layer.

FIGS. 4A, 4B and 4C are cross sectional views of the exemplary structure shown in FIGS. 3A, 3B and 3C, respectively, after forming a first lithographic stack of a first masking layer, a first anti-reflective coating layer, and a first photoresist material layer on the MOL dielectric layer, in which the first photoresist material layer has an opening that is located above the gate cut trench structure.

FIGS. 5A, 5B and 5C are cross sectional views of the exemplary structure shown in FIGS. 4A, 4B and 4C, respectively, after performing an etch to physically expose the gate cut trench structure, and removing the first photoresist material layer of the first lithographic stack.

FIGS. 6A, 6B and 6C are cross sectional views of the exemplary structure shown in FIGS. 5A, 5B and 5C, respectively, after removing a gate cut trench dielectric core structure of the gate cut trench structure to provide a VBPR opening that is located between gate cut dielectric spacers of the gate cut trench structure, and removing the first anti-reflective coating layer of the first lithographic stack.

FIGS. 7A, 7B and 7C are cross sectional views of the exemplary structure shown in FIGS. 6A, 6B and 6C, respectively, after removing the first masking layer of the first lithographic stack.

FIGS. 8A, 8B and 8C are cross sectional views of the exemplary structure shown in FIGS. 7A, 7B and 7C, respectively, after forming a second lithographic stack of a second masking layer, a second anti-reflective coating layer, and a second photoresist material layer on the MOL dielectric layer, in which the second photoresist material layer has openings that are located above each of the source/drain regions of the first and second nanosheet transistors.

FIGS. 9A, 9B and 9C are cross sectional views of the exemplary structure shown in FIGS. 8A, 8B and 8C, respectively, after performing an etch to open the second anti-reflective coating layer and the second masking layer of the second lithographic stack and removing the second photoresist material layer.

FIGS. 10A, 10B and 10C are cross sectional views of the exemplary structure shown in FIGS. 9A, 9B and 9C, respectively, after forming frontside source/drain contact openings in the MOL dielectric layer, and removing the second anti-reflective coating layer of the second lithographic stack.

FIGS. 11A, 11B and 11C are cross sectional views of the exemplary structure shown in FIGS. 10A, 10B and 10C, respectively, after removing the second masking layer of the second lithographic stack, in which after the removal of the second masking layer one of the frontside source/drain contact openings merges with the VBPR opening to provide a merged frontside source/drain contact/VBPR opening.

FIGS. 12A, 12B and 12C are cross sectional views of the exemplary structure shown in FIGS. 11A, 11B and 11C, respectively, after forming frontside gate contact openings, and filling each of the frontside source/drain contact openings, the frontside gate contact openings, and the merged frontside source/drain contact/VBPR opening with at least a conductive contact metal to provide frontside source/drain contact structures, frontside gate contact structures, and a merged frontside source/drain contact/VBPR structure, respectively, the merged frontside source/drain contact/VBPR structure includes a frontside source/drain contact structure and a VBPR structure that are merged together.

FIGS. 13A, 13B and 13C are cross sectional views of the exemplary structure shown in FIGS. 12A, 12B and 12C, respectively, after forming a first interconnect dielectric layer.

FIGS. 14A, 14B and 14C are cross sectional views of the exemplary structure shown in FIGS. 13A, 13B and 13C, respectively, after forming metal vias in the first interconnect dielectric layer.

FIGS. 15A, 15B and 15C are cross sectional views of the exemplary structure shown in FIGS. 14A, 14B and 14C, respectively, after forming a second interconnect dielectric layer that includes metal lines present therein, in which the second interconnect dielectric layer, the metal lines, the first interconnect dielectric layer and the metal vias collectively provide a lower interconnect level of a frontside back-end-of-the-line (BEOL) structure.

FIGS. 16A, 16B and 16C are cross sectional views of the exemplary structure shown in FIGS. 15A, 15B and 15C, respectively, after forming additional interconnect levels of the frontside BEOL structure on the lower interconnect level, and bonding the additional interconnect levels of the frontside BEOL structure to a carrier wafer.

FIGS. 17A, 17B and 17C are cross sectional views of the exemplary structure shown in FIGS. 16A, 16B and 16C, respectively, after flipping the structure and removing a semiconductor base layer of the substrate to physically expose an etch stop layer of the substrate.

FIGS. 18A, 18B and 18C are cross sectional views of the exemplary structure shown in FIGS. 17A, 17B and 17C, respectively, after removing the physically exposed etch stop layer of the substrate to reveal the semiconductor device layer of the substrate.

FIGS. 19A, 19B and 19C are cross sectional views of the exemplary structure shown in FIGS. 18A, 18B and 18C, respectively, after recessing the semiconductor device layer.

FIGS. 20A, 20B and 20C are cross sectional views of the exemplary structure shown in FIGS. 19A, 19B and 19C, respectively, after forming a backside ILD layer.

FIGS. 21A, 21B and 21C are cross sectional views of the exemplary structure shown in FIGS. 20A, 20B and 20C, respectively, after forming a backside power rail in physically contact with a lower portion of the VBPR structure.

FIG. 22 is a top down view of a semiconductor device in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside power rail. In some embodiments, the backside can also include a backside interconnect structure that is configured to deliver power to the transistor through the backside of the semiconductor device.

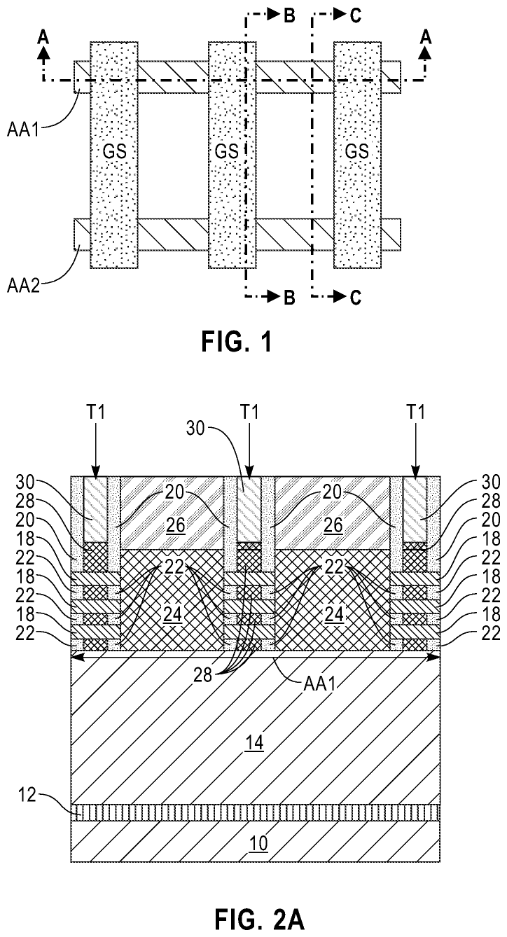

Referring first to FIG. 1, there is illustrated a device layout that can be used in the present application for forming a semiconductor device including a VBPR structure. The illustrated device layout includes a first active area AA1 and a second active area AA2 that are spaced apart by a non-active area. AA1 is an area in which first nanosheet transistors will be subsequently formed, while AA2 is an area in which second nanosheet transistors will be subsequently formed. The non-active area that is located between AA1 and AA2 is the area in which gate cutting will occur and in which a VBPR structure will be subsequently formed. The device layout further includes gate structures, GS, which run parallel to each other and perpendicular to each of the active areas. In the device layout shown in FIG. 1, cut A-A, cut B-B and cut C-C are shown. Cut A-A is a cut through the lengthwise direction of AA1. Cut B-B, which is perpendicular to cut A-A, is a cut through the lengthwise direction of the middle gate structure. Cut C-C is a cut in an area between the middle gate structure and the gate structure on the right hand side of the middle gate structure which passes through a source/drain region in AA1, a portion of the non-active device area, and a source/drain region in AA2. These three cuts will be used in describing various processing steps of the present application.

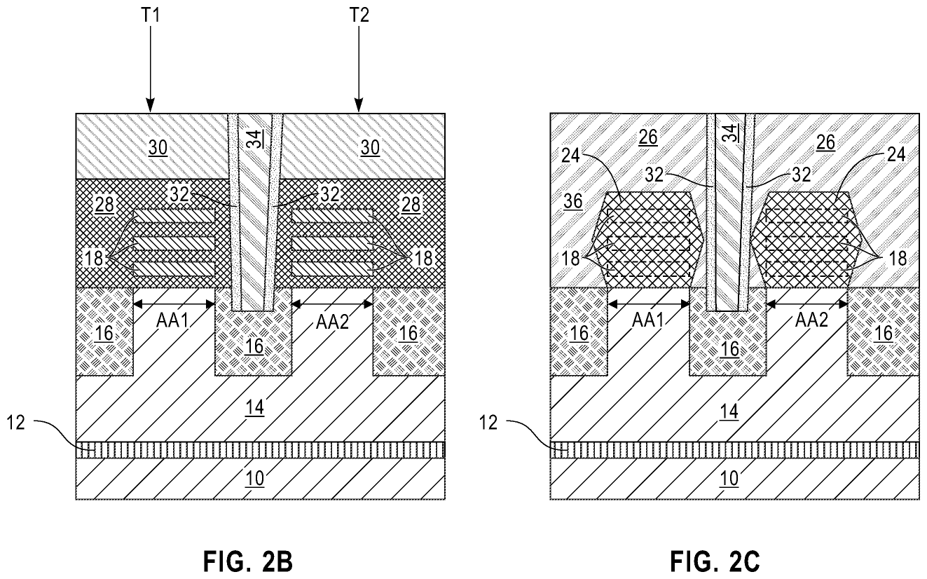

Referring now to FIGS. 2A, 2B and 2C, there are illustrated an exemplary structure through cut A-A, cut B-B, and cut C-C illustrated in FIG. 1, respectively, that can be employed in accordance with an embodiment of the present application. The exemplary structure illustrated in FIGS. 2A, 2B and 2C includes first nanosheet transistors T1 located in AA1 of a semiconductor device layer 14 of a substrate, and second nanosheet transistors T2 located in AA2 of the semiconductor device layer 14. Although only a single second nanosheet transistor T2 is illustrated in FIG. 2B, a plurality of second nanosheet transistors T2 would be present along a lengthwise direction of AA2 similar to the plurality of first transistors T1 illustrated in FIG. 2A. In the present application, a shallow trench dielectric structure 16 is present between AA1 and AA2.

Each of the first nanosheet transistors T1 and each of the second nanosheet transistors T2 includes a plurality of vertically stacked and spaced apart semiconductor channel material nanosheets 18, a gate structure 28 wrapped around each of the plurality of vertically stacked and spaced apart semiconductor channel material nanosheets 18, source/drain region 24 located on each side of the gate structure 28. Each of the first nanosheet transistors T1 and each of the second nanosheet transistors T2 further includes a gate cap 30 located on the gate structure 28, a gate spacer 20 present along a sidewall of the gate structure 28, and inner spacers 22 located beneath each of the ends of the semiconductor channel material nanosheets 18. The exemplary structure illustrated in FIGS. 2B and 2C further includes a gate cut trench structure (including gate cut dielectric spacers 32 and a gate cut core dielectric structure 34) separating each first nanosheet transistor T1 from each second nanosheet transistor T2. The gate cut trench structure includes a lower portion that extends into the shallow trench dielectric isolation structure 16 that is present in the non-active area between AA1 and AA2. In addition to the semiconductor device layer 14, the substrate can also include a base semiconductor layer 10 and/or an etch stop layer 12. The base semiconductor layer 10 and/or the etch stop layer 12 are optional components of the substrate.

The base semiconductor layer 10 is composed of a first semiconductor material, and the semiconductor device layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor base layer 14 can be compositionally the same as, or compositionally different from, the first semiconductor material that provides the semiconductor base layer 10.

In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

The substrate including the semiconductor base layer 10, the etch stop layer 12 and the semiconductor device layer 14 can be formed utilizing techniques well known to those skilled in the art. For example, the substrate including the semiconductor base layer 10, the etch stop layer 12 and the semiconductor device layer 14 can be formed by a separation by ion implantation of oxygen process, or wafer bonding. Alternatively, the substrate including the semiconductor base layer 10, the etch stop layer 12 and the semiconductor device layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

The shallow trench isolation structure 16 can be composed of any trench dielectric material such as, for example, silicon oxide. In some embodiments, a trench dielectric liner material such as, for example, SiN can be present along a sidewall and a bottom wall of the trench dielectric material. In some embodiments, the shallow trench isolation structure 16 can have a topmost surface that is substantially coplanar with a topmost surface of the semiconductor device layer 14. In other embodiments, the shallow trench isolation structure 16 can have a topmost surface that is vertically offset (i.e., higher or lower) than a topmost surface of the semiconductor device layer 14.

Each semiconductor channel material nanosheet 18 is composed of a fourth semiconductor material. The fourth semiconductor material that provides each semiconductor channel material nanosheet 18 can be compositionally the same as, or compositionally different from, the second semiconductor material that provides the semiconductor device layer 14. In some embodiments, the fourth semiconductor material that provides each semiconductor channel material nanosheet 18 provides high channel mobility for nFET devices. In other embodiments, the fourth semiconductor material that provides each semiconductor channel material nanosheet 18 provides high channel mobility for pFET devices. In one example, each semiconductor channel material nanosheet 18 is composed of silicon. Although the present application describes an embodiment in which the semiconductor channel material nanosheets 18 that are present in AA1 are composed of a compositionally same semiconductor material as the semiconductor channel material nanosheets 18 that are present in AA2, embodiments are possible in which the semiconductor channel material nanosheets 18 that are present in AA1 are composed of a compositionally different semiconductor material as the semiconductor channel material nanosheets 18 that are present in AA2. Also, and although the present application illustrates an embodiment in which the number of semiconductor channel material nanosheets 18 that are present in AA1 is the same as the number of semiconductor channel material nanosheet 18 present in AA2, embodiments are possible in which the number of semiconductor channel material nanosheets 18 that are present in AA1 is different from the number of semiconductor channel material nanosheets 18 that are present in AA2.

The gate spacer 20 and the inner spacer 22 are composed of a spacer dielectric material including, but not limited to, silicon dioxide, SiN, SiBCN, SiOCN or SiOC. The gate spacer 20 can be composed of a compositionally same spacer dielectric material as, or a compositionally different spacer dielectric material than, the inner spacers 22.

The source/drain regions 24 extend outward from a sidewall of each semiconductor channel material nanosheet 18. It is noted that in FIG. 2C, the source/drain region 24 on the far left hand side and present in AA1 represents one of the source/drain regions of the first nanosheet transistor T1, while the source/drain region 24 on the far right hand side and present in AA2 represents one of the source/drain regions of the second nanosheet transistor T2. The other source/drain region of the respective nanosheet transistor runs into or out of the plane of the drawing sheet including FIG. 2C. Also, in FIG. 2C, each semiconductor channel material nanosheet 18 is represented by dotted lines which denotes that the semiconductor channel material nanosheets 18 are located behind the source/drain regions 24 depicted in FIG. 2C.

Each source/drain region 24 is composed of a fifth semiconductor material and a dopant. As used herein, a “source/drain” region can be a source region or a drain region depending on subsequent wiring and application of voltages during operation of the transistor. The fifth semiconductor material that provides each source/drain region 24 is composed of one of the semiconductor materials mentioned above for the semiconductor base layer 10. The fifth semiconductor material that provides the source/drain regions 24 can be compositionally the same as, or compositionally different from, the fourth semiconductor material that provides each semiconductor channel material nanosheet 18. The dopant that is present in the source/drain regions 24 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions 24 can have a dopant concentration of from 4×10²⁰ atoms/cm³ to 3×10²¹ atoms/cm³.

The first frontside ILD layer 26 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted).

The gate structure 28 includes a gate dielectric material and a gate electrode, both of which are not separately shown, but intended to be within region defined by the gate structure 28. As is known to those skilled in the art, the gate dielectric material directly contacts a physically exposed surface(s) of the semiconductor channel region (e.g., each semiconductor channel material nanosheet 18), and the gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

The gate cap 30 is composed of a dielectric hard mask material including, but not limited to, silicon dioxide, silicon nitride and/or silicon oxynitride.

As mentioned above, the gate cut trench structure includes gate cut dielectric spacers 32 and gate cut core dielectric structure 34. The gate cut dielectric spacers 32 are composed of a first dielectric material, while the gate cut core dielectric structure 34 is composed of a second dielectric material that is compositionally different from the first dielectric material. In one example, the first dielectric material is silicon nitride, and the second dielectric material is silicon dioxide. Throughout the entire processing, the gate cut dielectric spacers 32 have a topmost surface the is substantially coplanar to the gate cap 30, and the topmost surface of each of the gate cut dielectric spacers 32 is above a topmost surface of the source/drain regions 24.

The exemplary structure illustrated in FIGS. 2A, 2B and 2C can be formed utilizing any well-known nanosheet transistor formation process, followed by cutting the gate structure 28 utilizing a conventional gate cut process. So not to obscure any aspect of the present application, details regarding the nanosheet transistor formation process and the gate cut process used in forming the exemplary structure shown in FIGS. 2A, 2B and 2C are not provided herein.

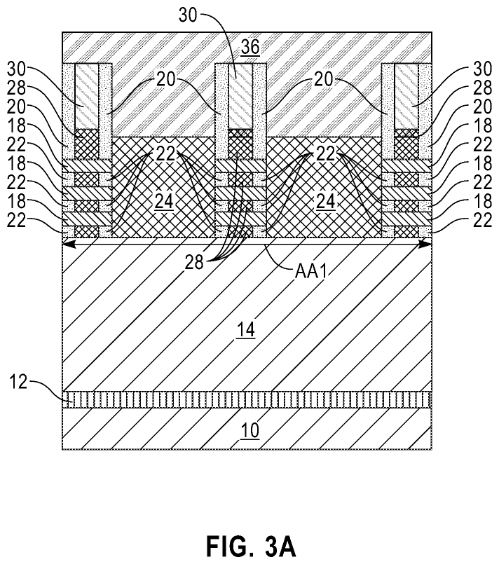

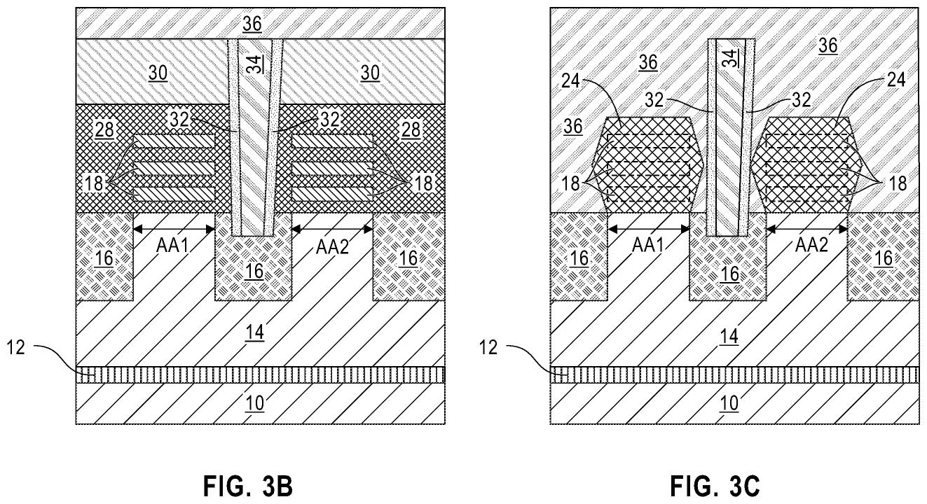

Referring now to FIGS. 3A, 3B and 3C, there are illustrated the exemplary structure shown in FIGS. 2A, 2B and 2C, respectively, after forming an additional frontside ILD material on a first frontside ILD layer that is located on the source/drain regions 24 of each first nanosheet transistor T1 and each second nanosheet transistor T2 and on top of the gate cap 30 and the gate cut trench structure (including gate cut dielectric spacers 32 and gate cut core dielectric structure 34 mentioned above). In the present application, the additional frontside ILD material and the first frontside ILD layer 26 collectively provide a middle-of-the-line (MOL) dielectric layer 36. The additional frontside ILD material can be composed of a dielectric material that is compositionally the same as, or compositionally different from, the dielectric material that provides the frontside ILD layer 26. Typically, the dielectric material that provides the additional ILD material is compositionally the same as the dielectric material that provides the frontside ILD layer 26 such that within the MOL dielectric layer 36 no material interface would exist between the additional frontside ILD material and the frontside ILD layer 26; such an embodiment is shown in the drawings of the present application. When compositionally different dielectric materials are employed for the additional frontside ILD material and the frontside ILD layer 26, the MOL dielectric layer 36 would contain a material interface between the two compositionally different dielectric materials. Such an embodiment is not however shown in the drawings of the present application. The additional frontside ILD material can be formed utilizing a same technique that is used in forming the frontside ILD layer 26. Notably, the additional frontside ILD material can be formed by a deposition process including, but not limited to, CVD, PECVD or spin-on coating. A planarization process such as, for example, chemical mechanical polishing (CMP) follows the deposition process.

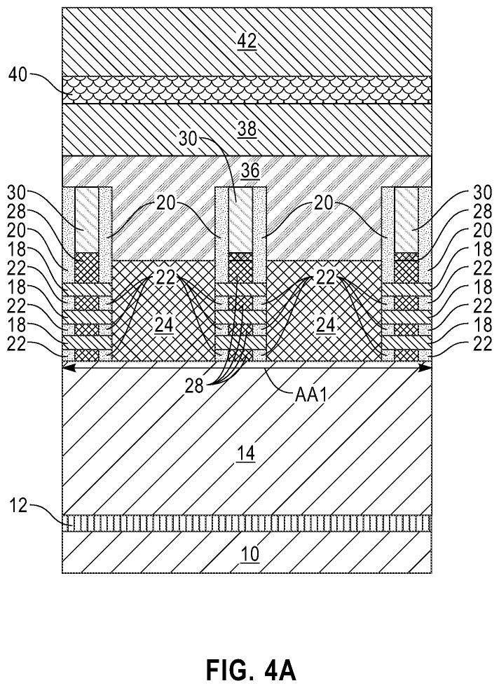

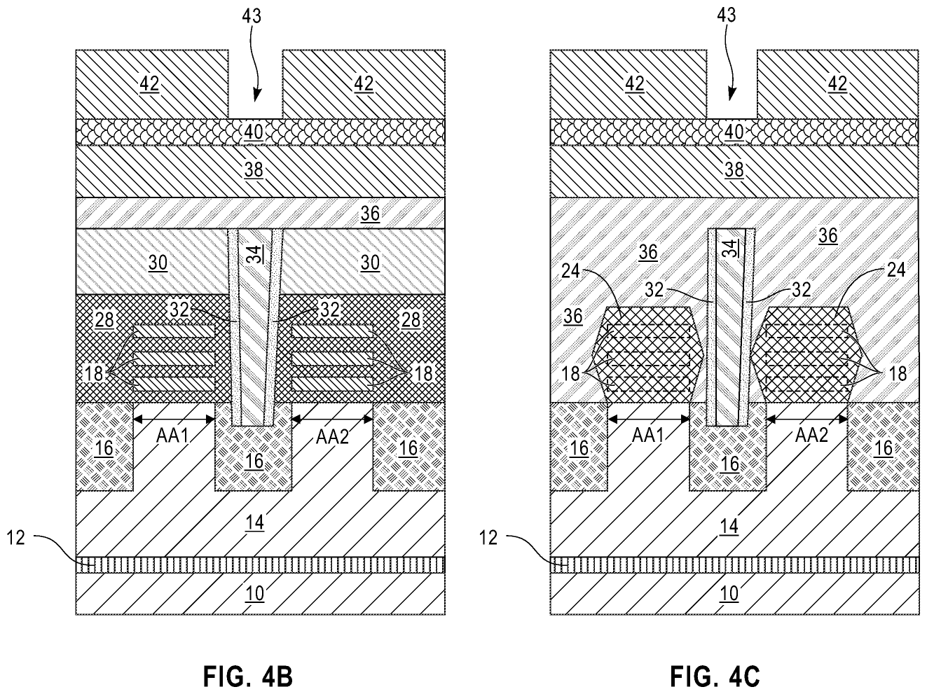

Referring now to FIGS. 4A, 4B and 4C, there are illustrated the exemplary structure shown in FIGS. 3A, 3B and 3C, respectively, after forming a first lithographic stack of a first masking layer 38, a first anti-reflective coating layer 40, and a first photoresist material layer 42 on the MOL dielectric layer 36. As is illustrated in FIGS. 4B and 4C, the first photoresist material layer 42 has an opening 43 that is located above the gate cut trench structure. The first lithographic stack is employed in the present application in defining an area in which a VBPR structure will be subsequently formed. The first masking layer 38 can be composed of a masking material or a combination of masking materials. In one example, first masking layer 38 can include an organic planarization material. The first masking layer 38 can be formed by a deposition process such as, for example, CVD, PECVD or spin-on coating. First anti-reflective coating layer 40 can be composed of any anti-reflective coating (ARC) material that is used in lithographic patterning. In one example, the first anti-reflective coating layer 40 can be composed of a Si-ARC. The first anti-reflective coating layer 40 can be formed by a deposition process such as, for example, CVD, PECVD or spin-on coating. The first photoresist material layer 42 can be composed of any conventional photoresist material. The first photoresist material layer 42 can be formed by a deposition process such as, for example, CVD, PECVD or spin-on coating. Opening 43 can be formed into the first photoresist material layer 42 by exposing the as-deposited photoresist material to a desired pattern of irradiation and thereafter developing the exposed photoresist material. Opening 43 physically exposes a surface of the underlying first anti-reflective coating layer 40.

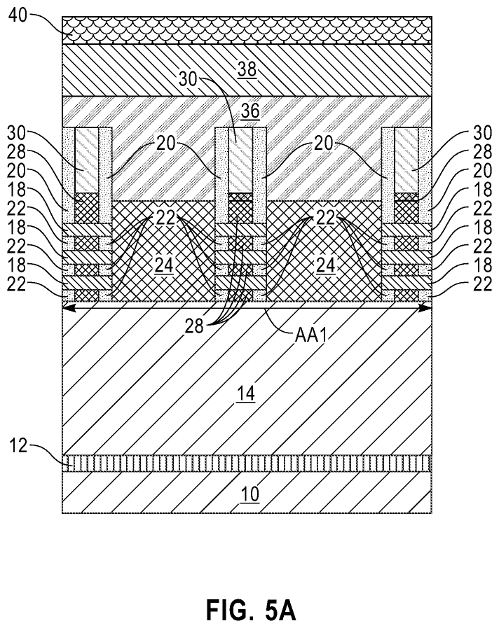

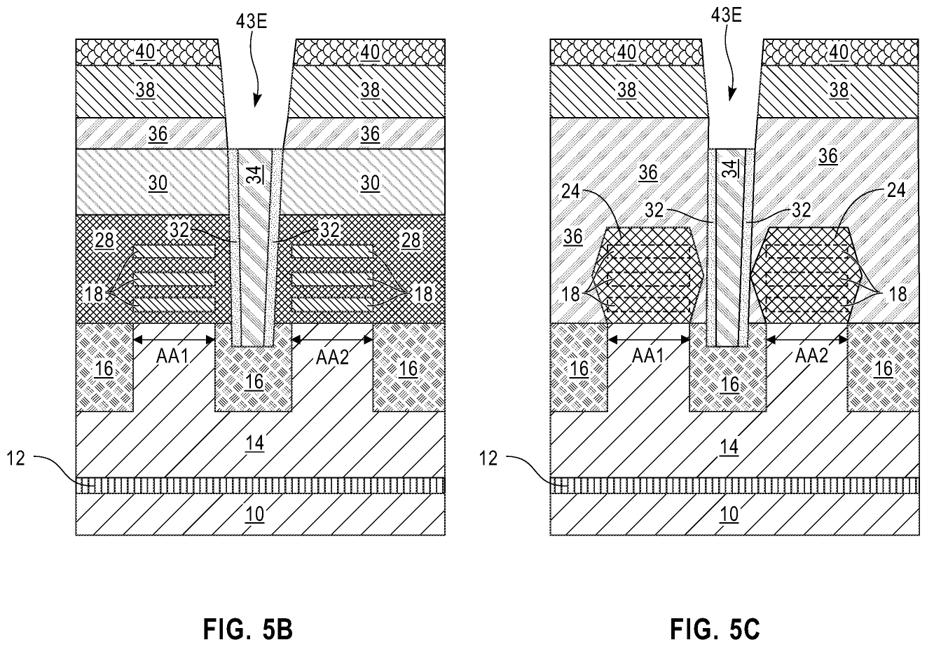

Referring now to FIGS. 5A, 5B and 5C, there are illustrated the exemplary structure shown in FIGS. 4A, 4B and 4C, respectively, after performing an etch to physically expose the gate cut trench structure, and removing the first photoresist material layer 42 of the first lithographic stack. The etch extends the opening 43 by etching through the first anti-reflective coating layer 40, the first masking layer 38 and the MOL dielectric layer 36. The etch stops on a topmost surface of the gate cut trench structure. Thus, the etch physically exposes a topmost surface of each of the gate cut dielectric spacers 32 and the gate cut core dielectric structure 34 as is illustrated in FIGS. 5B and 5C. Extended opening 43E is formed by this etch. The etch can include a dry etching process such as, for example, reactive ion etching (RIE), plasma etching or ion beam etch. The first photoresist material layer 42 of the first lithographic stack can be removed any time after the etch transfers the patterned provided by opening 43 into at least the first anti-reflective coating layer 40. The first photoresist material layer 42 can be removed utilizing any well-known resist removal process.

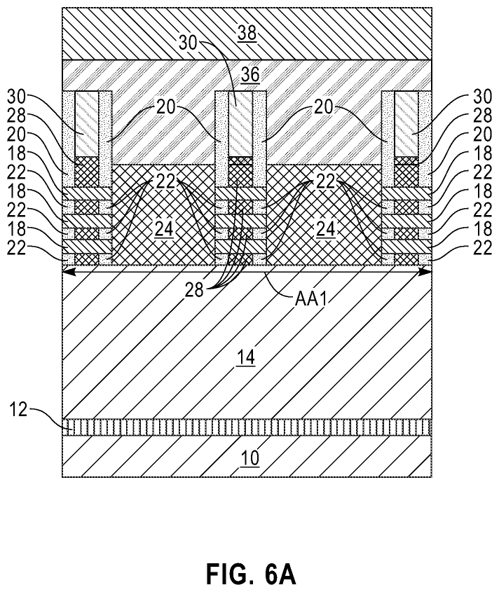

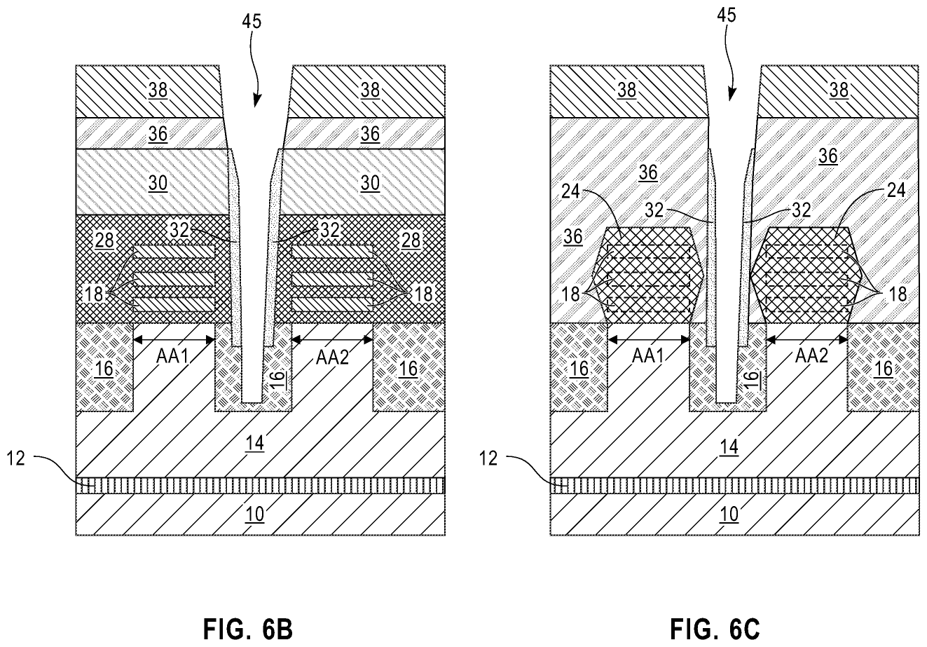

Referring now to FIGS. 6A, 6B and 6C, there are illustrated the exemplary structure shown in FIGS. 5A, 5B and 5C, respectively, after removing the gate cut trench dielectric core structure 34 of the gate cut trench structure to provide a VBPR opening 45 that is located between the gate cut dielectric spacers 32 of the gate cut trench structure (VBPR opening 45 extends into the shallow trench isolation structure 16 that is located between AA1 and AA2), and removing the first anti-reflective coating layer 40 of the first lithographic stack. The gate cut trench dielectric core structure 34 can be removed utilizing an etching process such as, for example, RIE, that is selective in removing the second dielectric material that provides the gate cut trench dielectric core structure 34 relative to the first dielectric material that provides the gate cut dielectric spacers 32. While the etch is selective in removing the second dielectric material relative to the first dielectric material, the etch can remove an upper portion of each of the gate cut dielectric spacers 32 such that the upper portion of the gate cut dielectric spacers 32 has a slightly tapered profile as illustrated in FIGS. 6B and 6C. The etch can stop within the shallow trench dielectric isolation structure 16, or it can stop on a topmost surface of the semiconductor device layer 14. In the illustrated embodiment shown in FIGS. 6B and 6C, the etch stops on a sub-surface of the shallow trench isolation structure 16 that is located between AA1 and AA2. The term “sub-surface” denotes a surface of a layer or structure that is located between a topmost surface and a bottommost surface of the same layer or structure. The first anti-reflective coating layer 40 can be removed utilizing any well-known ARC removal process.

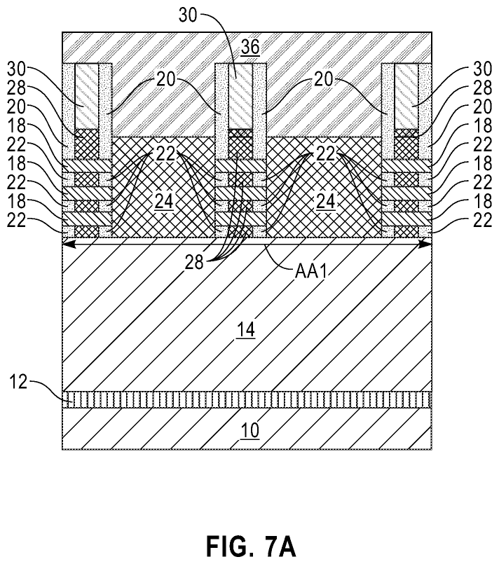

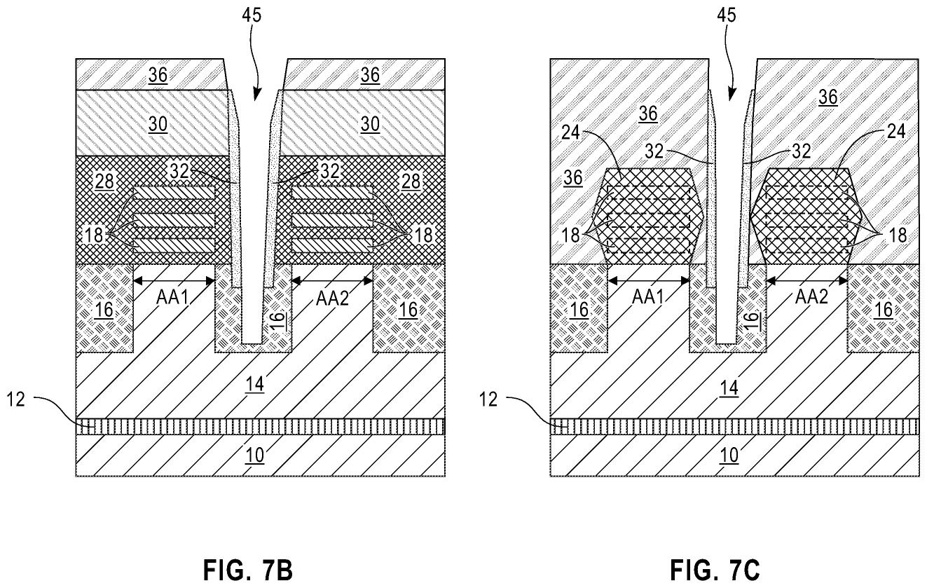

Referring now to FIGS. 7A, 7B and 7C, there are illustrated the exemplary structure shown in FIGS. 6A, 6B and 6C, respectively, after removing the first masking layer 38 of the first lithographic stack. The first masking layer 38 can be removed utilizing a material removal process that is selective in removing the first masking layer 38. In one example, the first masking layer 38 can be removed utilizing an ashing process. After removal of the first masking layer 38, the MOL dielectric layer 36 is physically exposed as shown in FIGS. 7A, 7B and 7C.

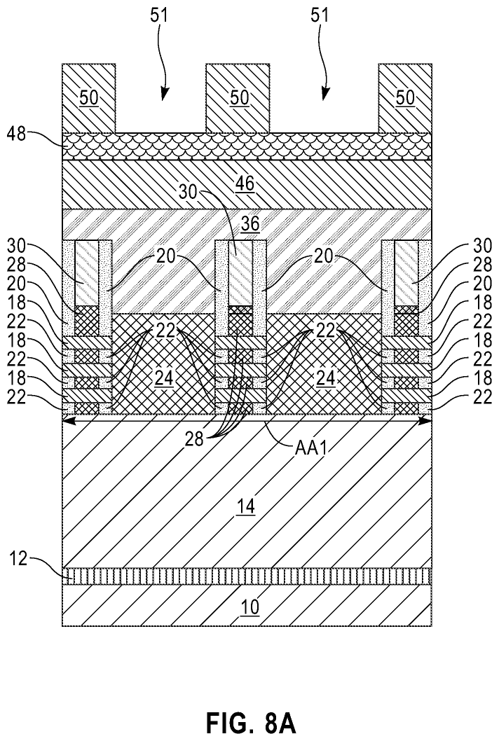

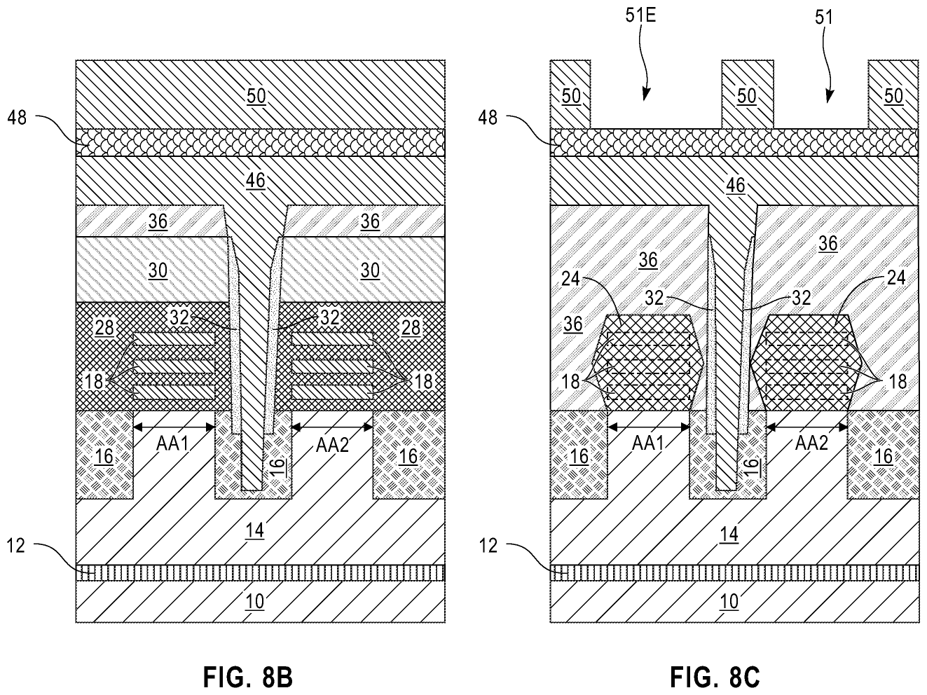

Referring now to FIGS. 8A, 8B and 8C, there are illustrated the exemplary structure shown in FIGS. 7A, 7B and 7C, respectively, after forming a second lithographic stack of a second masking layer 46, a second anti-reflective coating layer 48, and a second photoresist material layer 50 on the MOL dielectric layer 36. The second photoresist material layer 50 has openings 51 that are located above each of the source/drain regions 24 of the first and second nanosheet transistors, T1 and T2, respectively. The second masking layer 46 can be composed of a masking material or a combination of masking materials. In one example, second masking layer 46 can include an organic planarization material. The second masking layer 46 can be formed by a deposition process such as, for example, CVD, PECVD or spin-on coating. The second masking layer 46 is formed on top of the MOL dielectric layer 36 and completely within the VBPR opening 45 as is shown in FIGS. 8B and 8C. Second anti-reflective coating layer 48 can be composed of any anti-reflective coating (ARC) material that is used in lithographic patterning. In one example, the second anti-reflective coating layer 48 can be composed of a Si-ARC. The second anti-reflective coating layer 48 can be formed by a deposition process such as, for example, CVD, PECVD or spin-on coating. The second photoresist material layer 50 can be composed of any conventional photoresist material. The second photoresist material layer 50 can be formed by a deposition process such as, for example, CVD, PECVD or spin-on coating. Openings 51 can be formed into the second photoresist material layer 50 by exposing the as-deposited photoresist material to a desired pattern of irradiation and thereafter developing the exposed photoresist material. Openings 51 physically expose a surface of the underlying second anti-reflective coating layer 40.

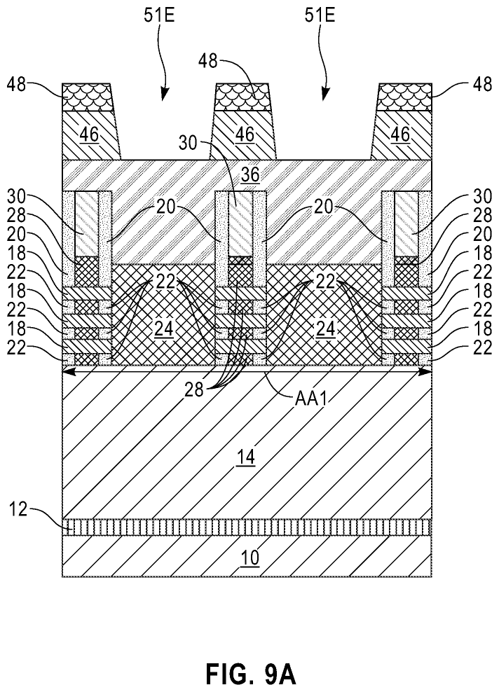

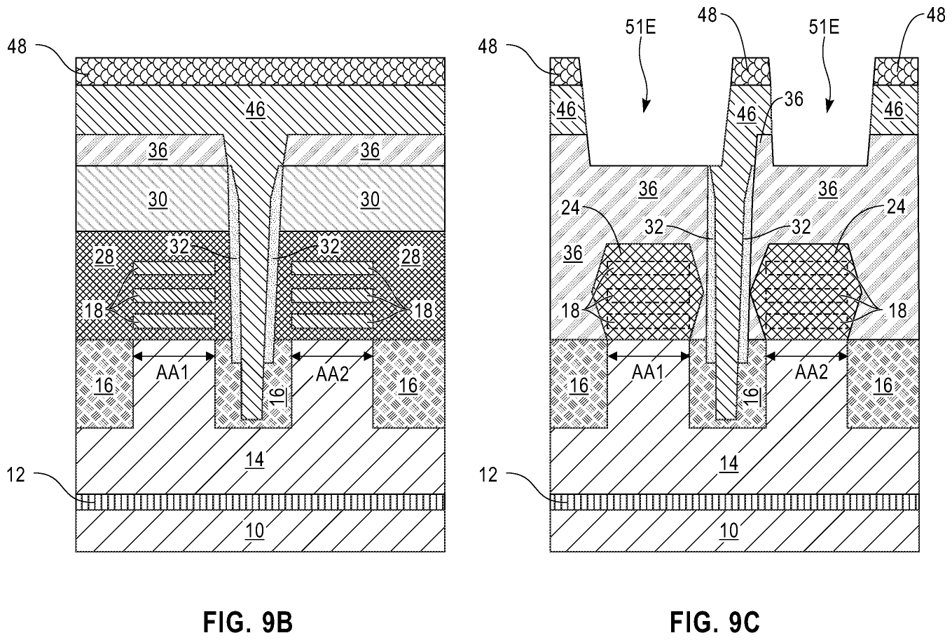

Referring now to FIGS. 9A, 9B and 9C, there are illustrated the exemplary structure shown in FIGS. 8A, 8B and 8C, respectively, after performing an etch to open the second anti-reflective coating layer 48 and the second masking layer 46 of the second lithographic stack and removing the second photoresist material layer 50. The etch includes extending the openings 51 by etching through the second anti-reflective coating layer 48 and the second masking layer 46. The etch can remove an upper portion of the MOL dielectric layer 36 that is present above the source/drain regions 24 of the first and second nanosheet transistors, T1 and T2, respectively, as is illustrated in FIG. 9C. The second masking layer 46 exists in the VBPR opening 45 and in an area directly on top of VBPR opening 45 which could be removed together post full frontside source/drain contacting opening formation and will improve the contact area in which the one of the frontside source/drain structures 56A is merged with the VBPR structure 58. Extended openings 51E are formed by this etch. The etch can include a dry etching process such as, for example, RIE, plasma etching or ion beam etch. The second photoresist material layer 450 of the second lithographic stack can be removed any time after the etch transfer the patterned provided by openings 51 into at least the second anti-reflective coating layer 48. The second photoresist material layer 50 can be removed utilizing any well-known resist removal process.

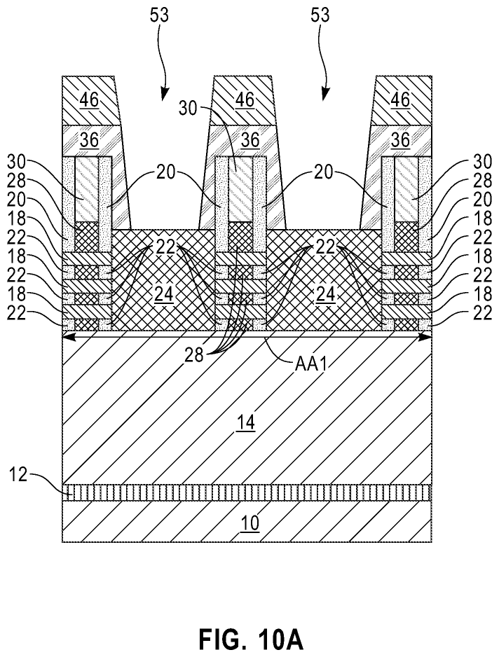

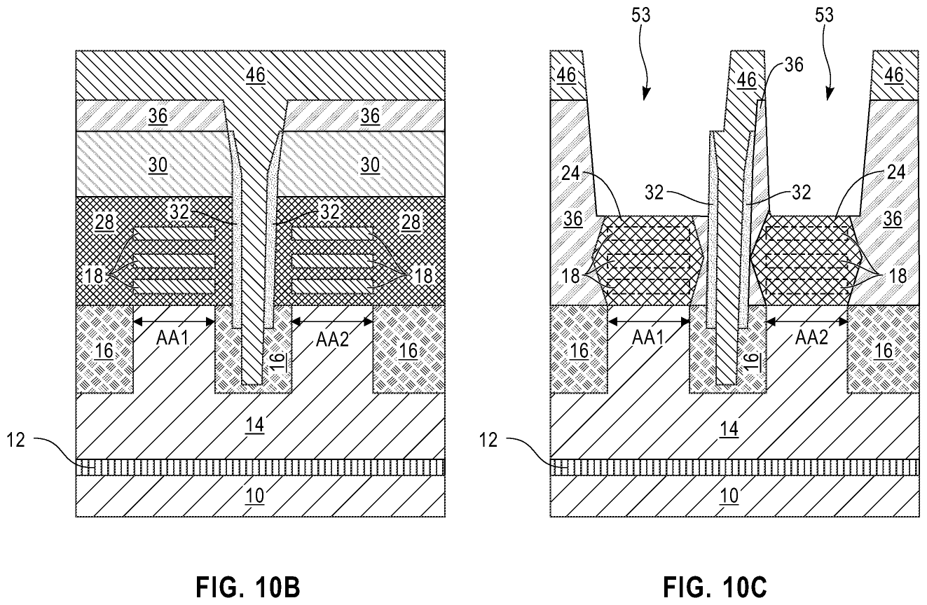

Referring now to FIGS. 10A, 10B and 10C, there are illustrated the exemplary structure shown in FIGS. 9A, 9B and 9C, respectively, after forming frontside source/drain contact openings 53 in the MOL dielectric layer 36, and removing the second anti-reflective coating layer 48 of the second lithographic stack. The frontside source/drain contact openings 53 can be formed by etching through the MOL dielectric layer 36 and stopping on the source/drain regions 24 of the first and second nanosheet transistors, T1 and T2, respectively. The etch, which occurs through the extended openings 51E, can remove an upper portion of source/drain regions 24 of the first and second nanosheet transistors, T1 and T2, respectively, as is illustrated in FIG. 10C. The etch is selective in removing the MOL dielectric layer 36 that is physically exposed by the extended openings 51E. The etch can include RIE. The second anti-reflective coating layer 48 can be removed utilizing any well-known ARC removal process.

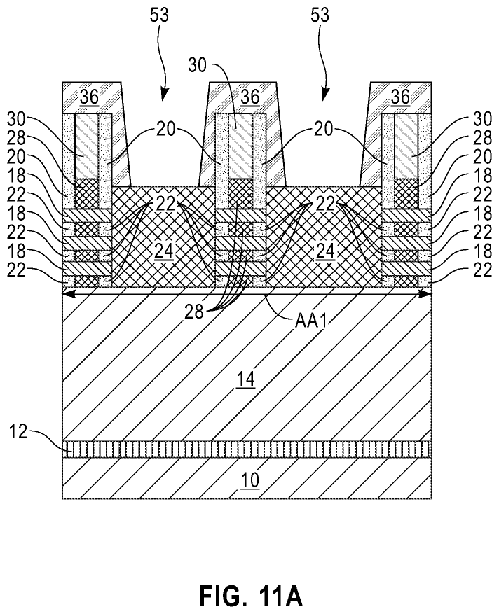

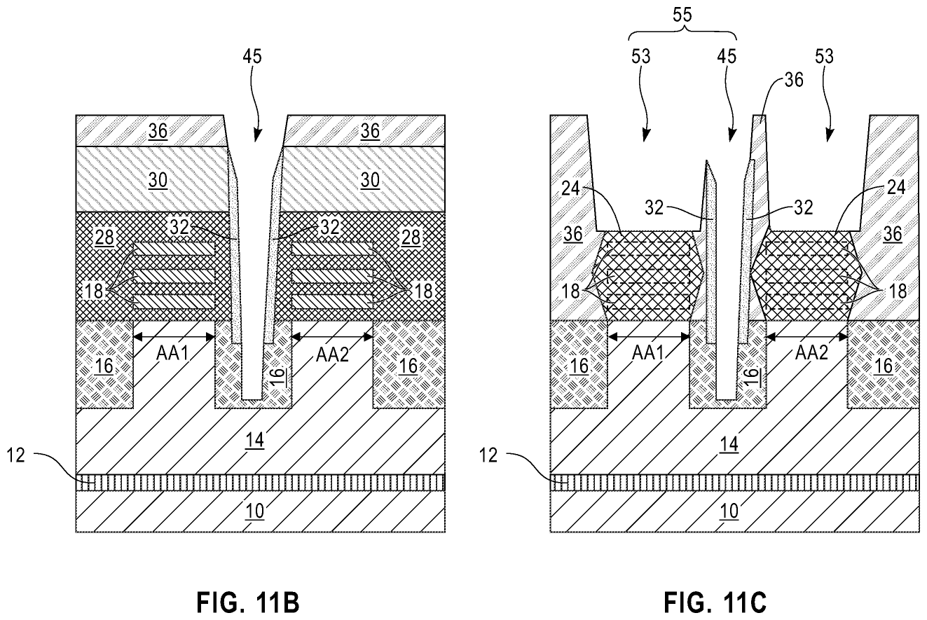

Referring now to FIGS. 11A, 11B and 11C, there are illustrated the exemplary structure shown in FIGS. 10A, 10B and 10C, respectively, after removing the second masking layer 46 of the second lithographic stack, in which after the removal of the second masking layer 46 one of the frontside source/drain contact openings 53 merges with the VBPR opening 45 to provide a merged frontside source/drain contact/VBPR opening 55. The removal of the second masking layer 46 includes a selective etching process such as, for example, RIE. The selective etch does not remove any significant portion of the gate cut dielectric spacers 32 and leads to improved overlap between frontside source/drain contact structure 53 and VBPR structure 58 of the subsequently formed merged frontside source/drain contact/VBPR structure 59. The gate cut dielectric spacers 32 have a topmost surface that is vertically offset and located beneath a topmost surface of the MOL dielectric layer 36, and the topmost surface of the gate cut dielectric spacers 32 are substantially coplanar with the gate cap 30 and is located above a topmost surface of the source/drain regions 24 of the first and second nanosheet transistors, T1 and T2, respectively. The gate cut dielectric spacers 32 also have a bottommost surface that lands on a sub-surface of the shallow trench isolation structure 16. The merged frontside source/drain contact/VBPR structure 59 can have a topmost surface that is substantially coplanar with a topmost surface of the MOL dielectric layer 36.

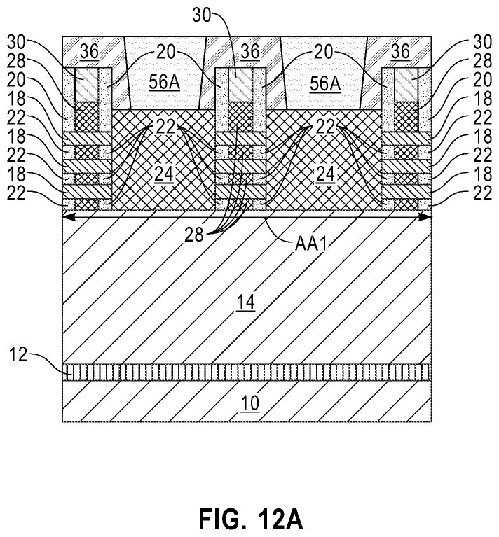

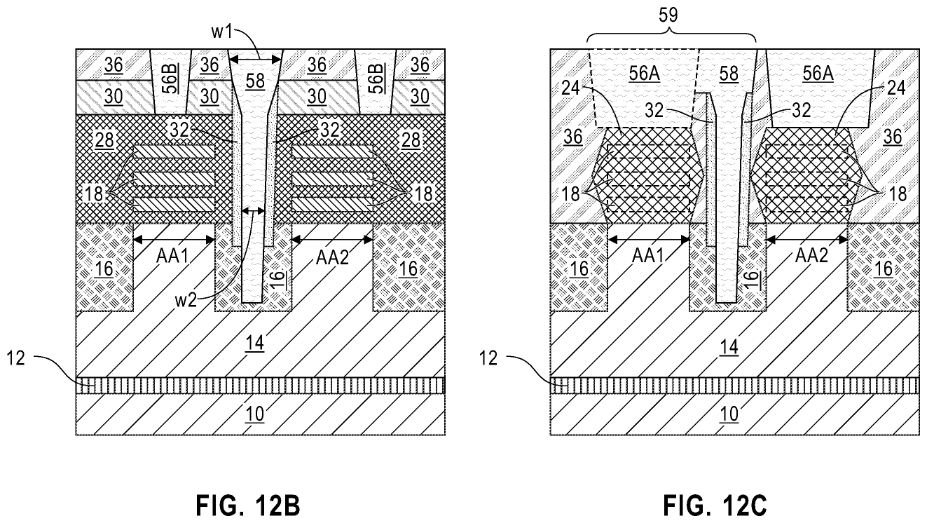

Referring now to FIGS. 12A, 12B and 12C, there are illustrated the exemplary structure shown in FIGS. 11A, 11B and 11C, respectively, after forming frontside gate contact openings (not specifically shown), and filling each of the frontside source/drain contact openings 53, the frontside gate contact openings, and the merged frontside source/drain contact/VBPR opening 55 with at least a conductive contact metal to provide frontside source/drain contact structures 56A, frontside gate contact structures 56B, and a merged frontside source/drain contact/VBPR structure 59, respectively, the merged frontside source/drain contact/VBPR structure 59 includes frontside source/drain contact structure 56A and VBPR structure 58 that are merged together. The frontside gate contact openings are formed by lithography and etching. The frontside gate contact openings physically expose a surface of the gate structure 28 of the first nanosheet transistor T1 and a surface of the gate structure 28 of the second nanosheet transistor T2. The frontside source/drain contact structures 56A that are not merged with the VBPR structure 58 can be referred to herein as a non-merged frontside source/drain contact structure. Each frontside source/drain contact structure 56A that is used as a component of the merged frontside source/drain contact/VBPR structure 59 can be referred to herein as a non-shared frontside source/drain contact structure; the non-shared frontside source/drain contact structures can be in electrical contact with the source/drain region of the first transistor that is not in electrical contact with the frontside source/drain contact structure of the merged frontside source/drain contact/VBPR structure.

The contact conductor material used in forming the frontside source/drain contact structures 56A, the frontside gate contact structures 56B, and the merged frontside source/drain contact/VBPR structure 59 includes, but is not limited to, W, Cu, Al, Co, Ru, Mo, Os, Ir, Rh, or an alloy thereof. In embodiments, the frontside source/drain contact structures 56A, the frontside gate contact structures 56B, and the merged frontside source/drain contact/VBPR structure 59 can also include a silicide liner such as TiSi, NiSi, NiPtSi, etc., and an adhesion metal liner, such as Ti, Ta, TiN, TiN or any combination thereof. The contact conductor material can be formed by any suitable deposition method such as, for example, atomic layer deposition (ALD), CVD, physical vapor deposition (PVD) or plating. The silicide liner and the adhesion metal liner can be formed utilizing techniques well-known in the art. After filling the frontside source/drain contact openings 53, the frontside gate contact openings, and the merged frontside source/drain contact/VBPR opening 55 with at least the contact conductor material, a planarization process can be employed to provide the exemplary structure shown in FIGS. 12A, 12B and 12C.

In the present application and as is illustrated in FIG. 12B, the VBPR structure 58 of the merged frontside source/drain contact/VBPR structure 59 has an upper portion that is located in, and in contact with, the MOL dielectric layer 36, a middle portion that is present between, and in contact with, the gate cut dielectric spacers 32, and a lower portion that is surrounded by the shallow trench dielectric structure 16. The upper portion of the VBPR structure 58 of the merged frontside source/drain contact/VBPR structure 59 has a first width and the middle portion of the VBPR structure 58 of the merged frontside source/drain contact/VBPR structure 59 has a second width that is less than the first width. The lower portion of the VBPR structure 58 of the merged frontside source/drain contact/VBPR structure 59 would have substantially the second width. That is, the lower portion of the VBPR structure 58 of the merged frontside source/drain contact/VBPR structure 59 has a width that is substantially equal to the second width.

In the present application and as is illustrated in FIG. 12B, the VBPR structure 58 of the merged frontside source/drain contact/VBPR structure 59 is electrically isolated from the gate structure 28 of the first and second nanosheet transistors, T1 and T2, respectively, by the gate cut dielectric spacers 32. As is shown in FIG. 12C, the gate cut dielectric spacers 32 also prevent contact between the VBPR structure 58 of the merged frontside source/drain contact/VBPR structure 59 and the source/drain regions 24 of the first and second nanosheet transistors, T1 and T2, respectively.

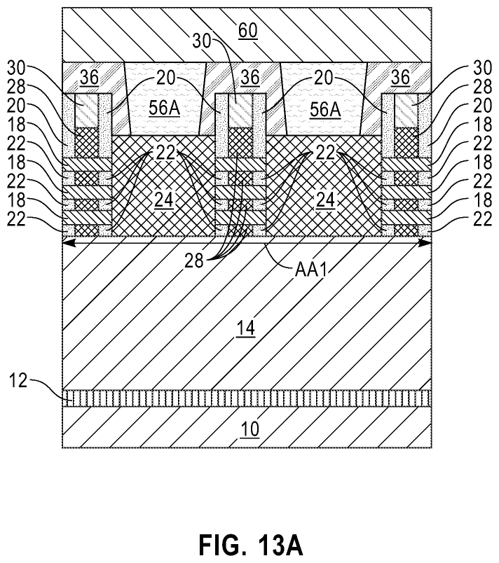

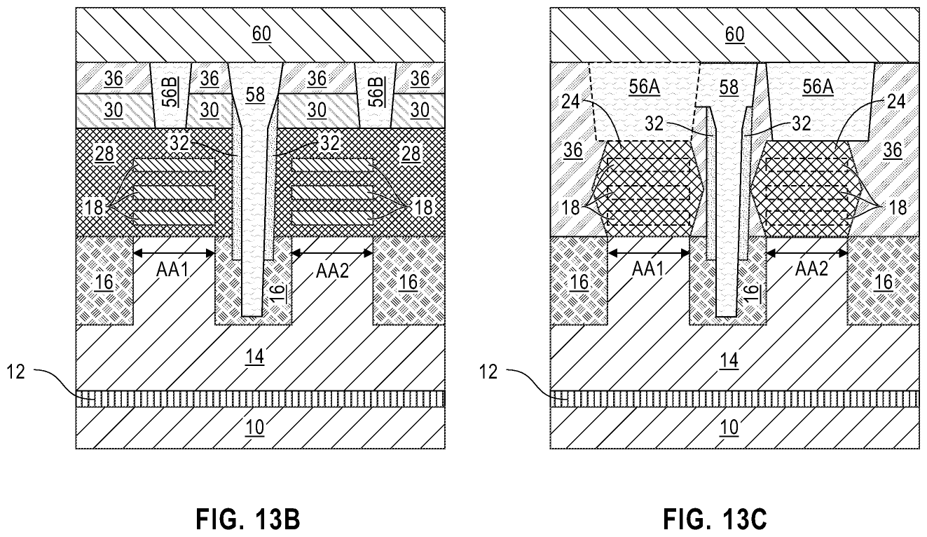

Referring now to FIGS. 13A, 13B and 13C, there are illustrated the exemplary structure shown in FIGS. 12A, 12B and 12C, respectively, after forming a first interconnect dielectric layer 60. The first interconnect dielectric layer 60 can be composed of one of the dielectric materials mentioned above for the first frontside ILD layer 26. The first interconnect dielectric layer 60 can be formed a deposition process including, but not limited to, CVD, PECVD or spin-on coating. A planarization process such as, for example, CMP can, but not necessarily always, follow the deposition process.

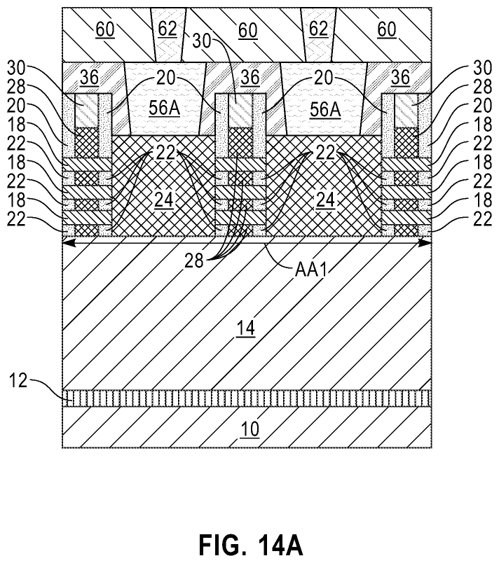

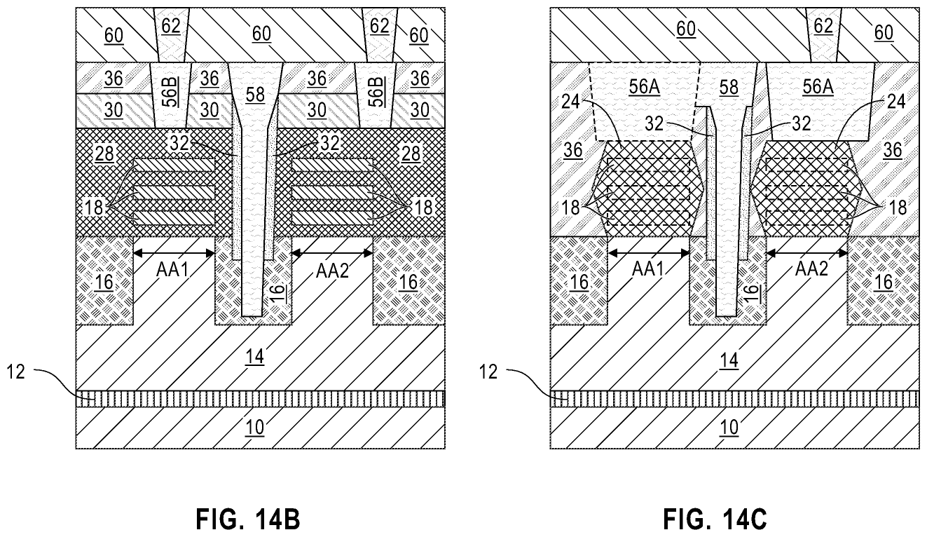

Referring now to FIGS. 14A, 14B and 14C, there are illustrated the exemplary structure shown in FIGS. 13A, 13B and 13C, respectively, after forming metal vias 62 in the first interconnect dielectric layer 60. The metal vias 62 are composed of an electrically conductive metal or an electrically conductive metal alloy. Illustrative examples of electrically conductive materials that can be used in forming the metal vias 62 include, but are not limited to, Cu, Al, W, Co, Ru or a Cu—Al alloy. The metal vias 62 can be formed by a damascene processes which can including forming via openings into the first interconnect dielectric layer 60 and then filling (by means of a deposition process such as, for example, CVD, PECVD, ALD, sputtering or plating) one of the electrically conductive materials mentioned above into the via openings, followed by a planarization process such as, for example, CMP. Although not shown, the metal vias 62 can be formed by a subtractive etch process and thereafter the first interconnect dielectric layer 60 is formed.

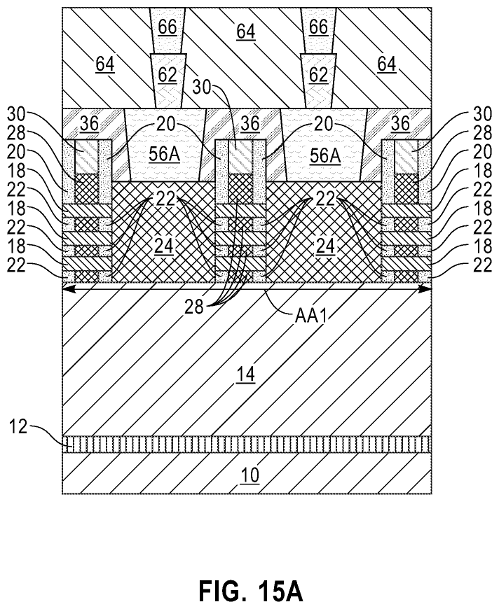

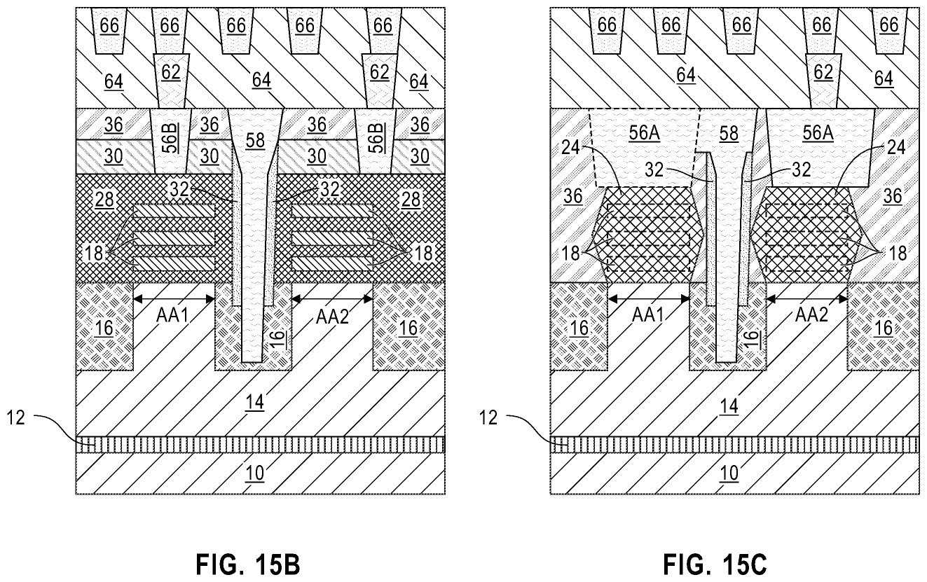

Referring now to FIGS. 15A, 15B and 15C, there are illustrated the exemplary structure shown in FIGS. 14A, 14B and 14C, respectively, after forming a second interconnect dielectric layer (not specifically shown) that includes metal lines 66 present in the second interconnect dielectric layer. The first interconnect dielectric layer 60, the metal vias 62, the second interconnect dielectric layer and the metal lines 66 collectively provide a lower interconnect level of a frontside BEOL structure. In the present application, the first interconnect dielectric layer 60 and the second interconnect dielectric layer collectively provide multilayered interconnect dielectric layer 64.

The second interconnect dielectric layer can be composed of one of the dielectric materials mentioned above for the first frontside ILD layer 26. The dielectric material that provides the second interconnect dielectric layer can be compositionally the same as, or compositionally different from the dielectric material that provides the first interconnect dielectric layer. The second interconnect dielectric layer can be formed a deposition process including, but not limited to, CVD, PECVD or spin-on coating. A planarization process such as, for example, CMP can, but not necessarily always, follow the deposition process.

The metal lines 66 are composed of an electrically conductive metal or an electrically conductive metal alloy as mentioned above for the metal vias 62. The electrically conductive material that provides the metal lines 66 can be compositionally the same as, or compositionally different from the electrically conductive material that provides the metal vias 62. The metal lines vias 62 can be formed by a damascene processes which can include forming line openings into the second interconnect dielectric layer and then filling (by means of a deposition process such as, for example, CVD, PECVD, ALD, sputtering or plating) one of the electrically conductive materials mentioned above in the metal line openings, followed by a planarization process such as, for example, CMP. Although not shown, the metal lines 66 can be formed by a subtractive etch process and thereafter the second interconnect dielectric layer is formed.

In the present application and as is shown in FIGS. 15A, 15B and 15C, some of the metal lines 66 are in direct contact with one of the underlying metal vias 62 that is in direct contact with the frontside source/drain contact structures 56A that are not merged with the VBPR 58, and some or the metal lines 66 are in direct contact with one of the underlying frontside gate contact structures 56B.

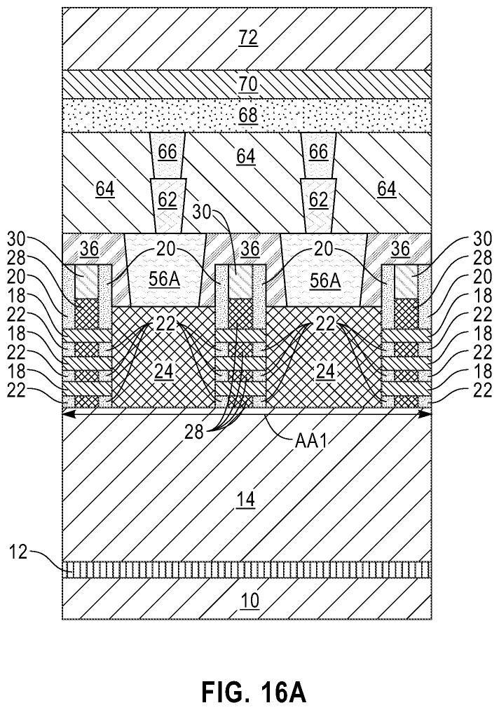

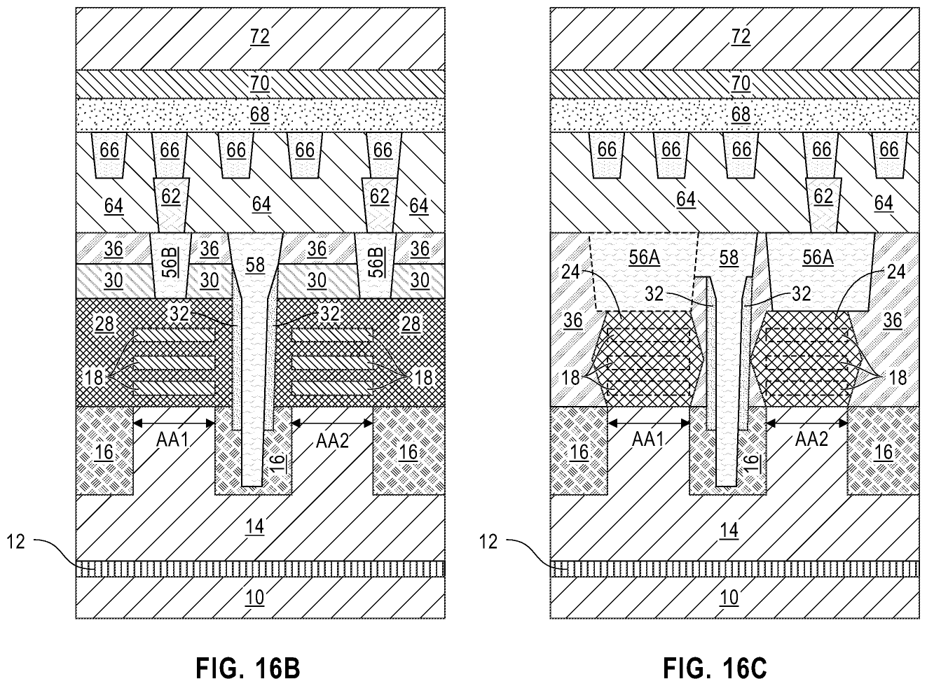

Referring now to FIGS. 16A, 16B and 16C, there are illustrated the exemplary structure shown in FIGS. 15A, 15B and 15C, respectively, after forming additional interconnect levels 68 of the frontside BEOL structure on the lower interconnect level, and bonding the additional interconnect levels 68 of the frontside BEOL structure to a carrier wafer 72. The additional interconnect levels 68 include one or more interconnect dielectric material layers (including one of the dielectric materials mentioned above for the frontside ILD layer 26) that contain furth frontside metal wires (the metal wires can be composed of any electrically conductive metal or electrically conductive metal alloy, as defined above) embedded therein. The additional interconnect levels 68 can include “x” numbers of frontside metal levels, in which “x” is an integer starting from 1. The additional interconnect levels can be formed utilizing techniques well known to those skilled in the art. In the present application, the frontside BEOL structure can be in electrical contact with the frontside source/drain contact structures 56A that are not merged with the VBPR 58 and the frontside gate contact structures 56B.

The carrier wafer 72 can include one of the semiconductor materials mentioned above for the semiconductor base layer 10. In the present application, the carrier wafer 72 can be bonded to additional interconnect levels 68 via a bonding layer 70. Bonding layer 70 can be a bonding oxide that is applied to either or both of the additional interconnect levels 68 and the carrier wafer 72 prior to bonding.

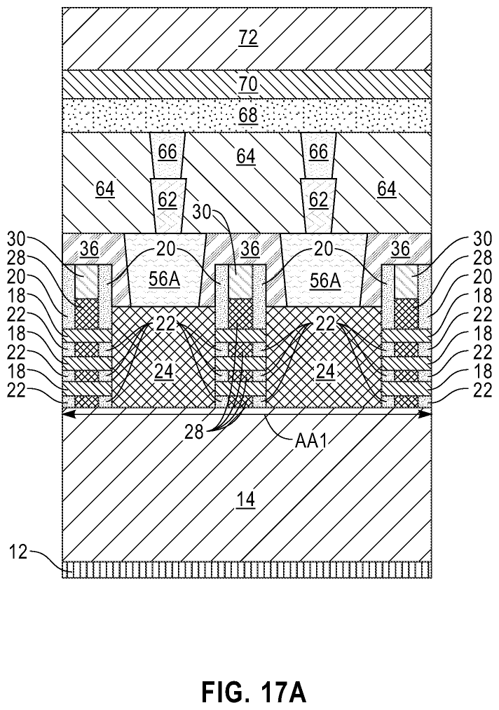

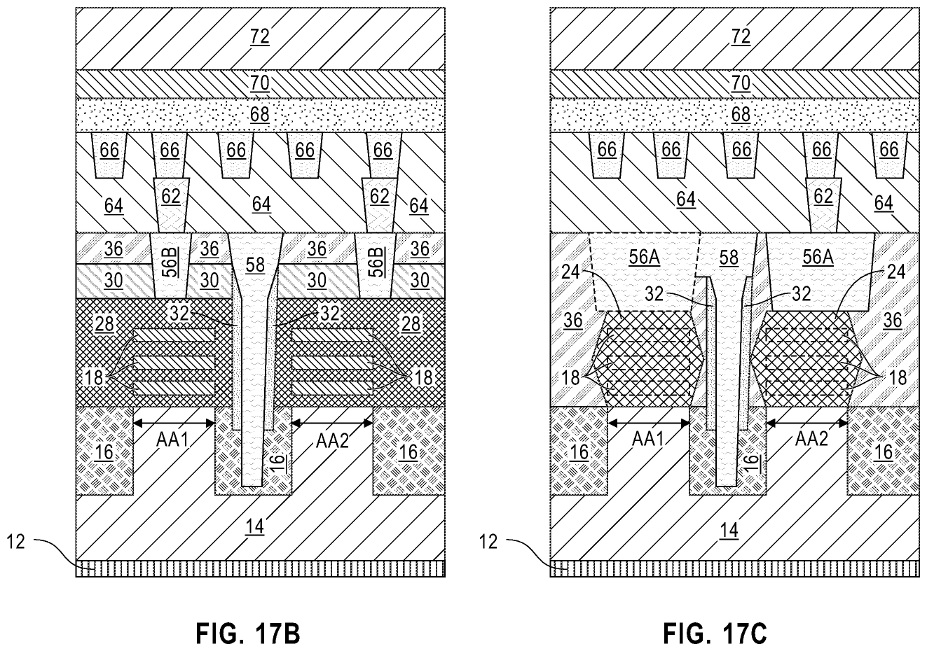

Referring now to FIGS. 17A, 17B and 17C, there are illustrated the exemplary structure shown in FIGS. 16A, 16B and 16C, respectively, after flipping the structure and removing the semiconductor base layer 10 of the substrate to physically expose the etch stop layer 12 of the substrate. In the present application, the structure shown in FIGS. 16A, 16B and 16C is flipped 180° to physically expose a backside of the substate. This flipping step is not shown in the drawings of the present application for clarity. This flipping step will allow backside processing of the exemplary structure. Backside processing occurs on a side of a substrate (or wafer) opposite the side where the first and second nanosheet transistors have been formed; in the present application the backside of the substrate can be defined as the area of the substrate that is beneath the semiconductor device layer 14. Flipping of the structure can be performed by hand or by utilizing a mechanical means such as, for example, a robot arm. The removal of the physically exposed semiconductor base layer 10 can be performed utilizing a material removal process that is selective in removing the first semiconductor material that provides the semiconductor base layer 10.

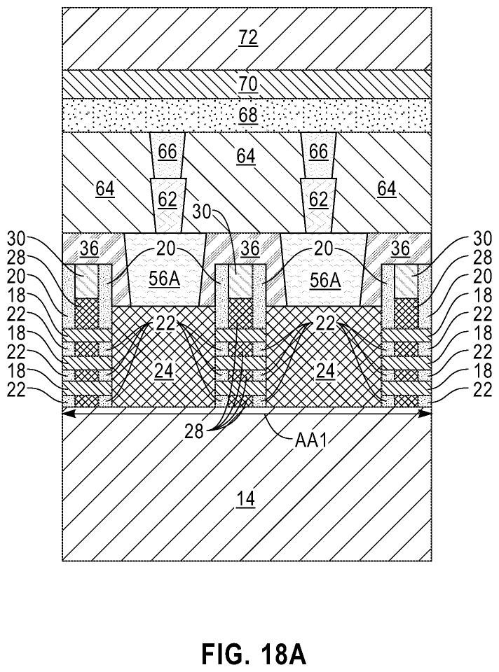

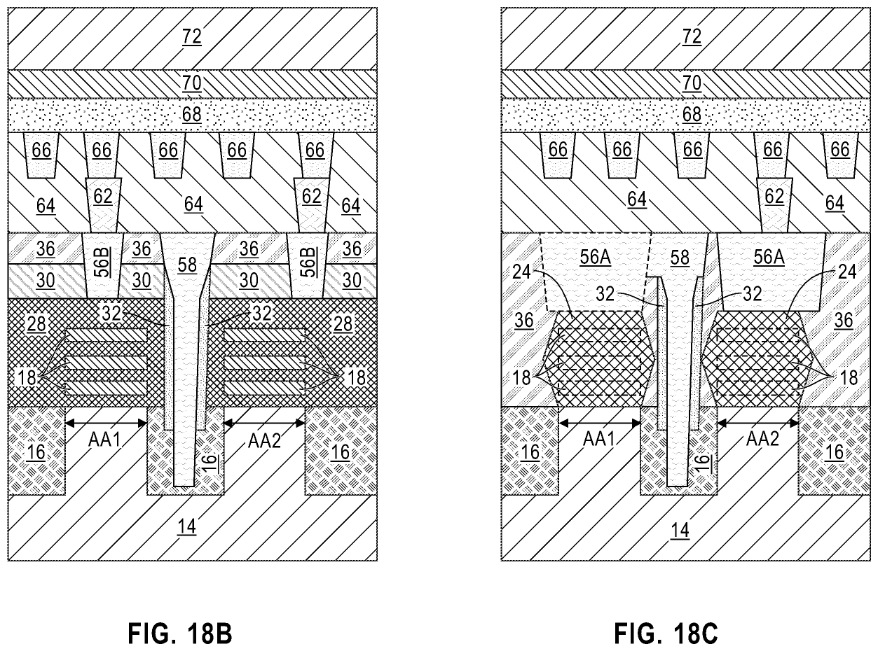

Referring now to FIGS. 18A, 18B and 18C, there are illustrated the exemplary structure shown in FIGS. 17A, 17B and 17C, respectively, after removing the physically exposed etch stop layer 12 of the substrate to reveal the semiconductor device layer 14 of the substrate. The removal of the physically exposed etch stop layer 12 can be performed utilizing a material removal process that is selective in removing the etch stop layer 12.

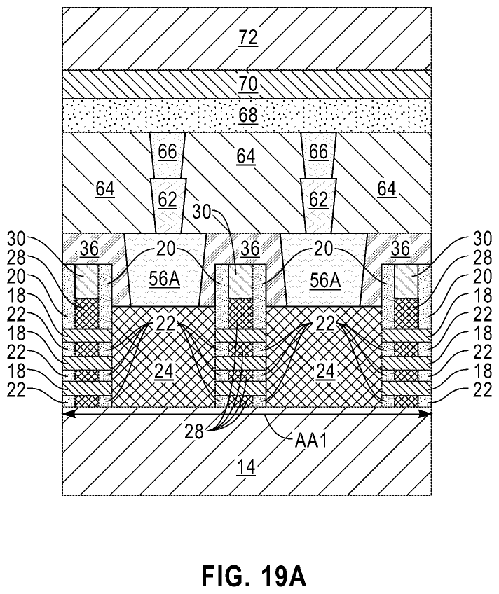

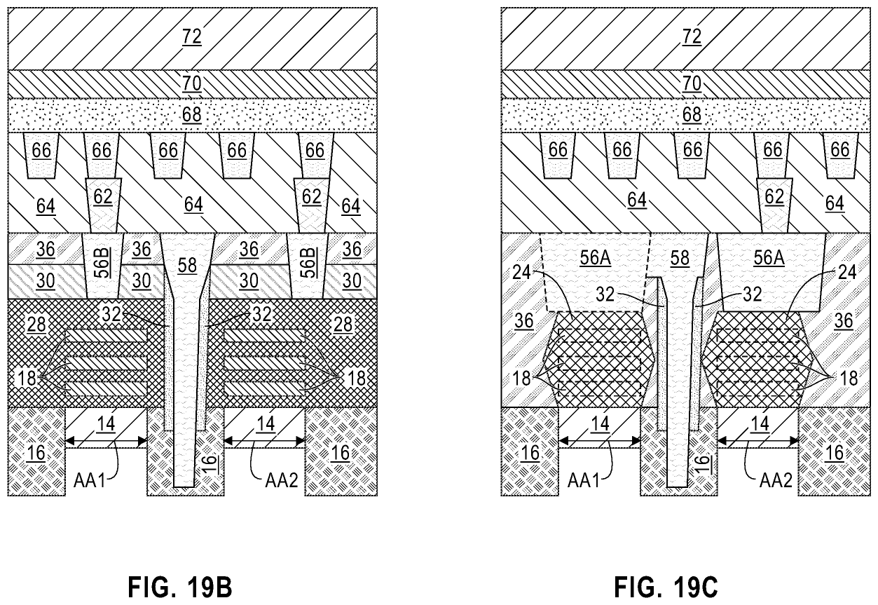

Referring now to FIGS. 19A, 19B and 19C, there are illustrated the exemplary structure shown in FIGS. 18A, 18B and 18C, respectively, after recessing the semiconductor device layer 14. The recessing of the semiconductor device layer 14 includes a recess etching process such as, RIE, that is selective in removing a portion of the semiconductor device layer 14. In the present application, the recessing thins the semiconductor device layer 14 from a first thickness to a second thickness such that the semiconductor device layer 14 that remains after recessing does not cover the bottommost surface of the shallow trench isolation structure 16 as is shown in FIGS. 19B and 19C.

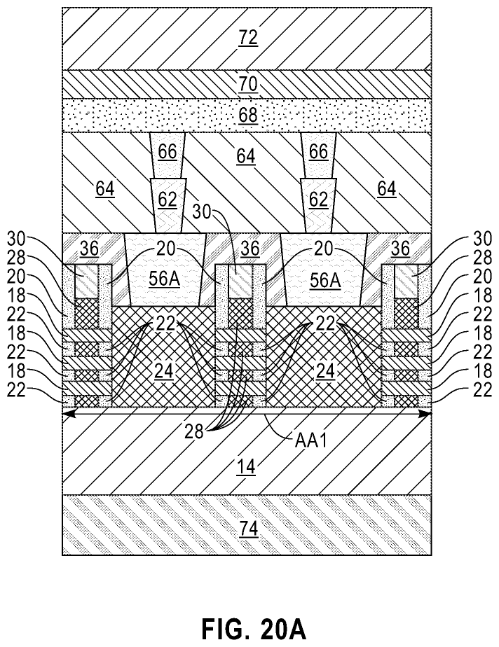

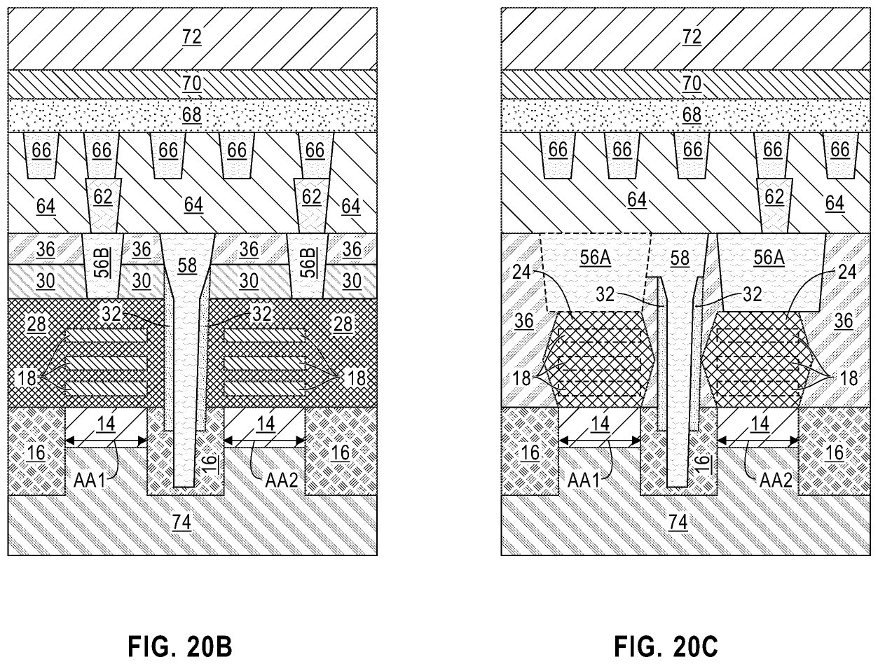

Referring now to FIGS. 20A, 20B and 20C, there are illustrated the exemplary structure shown in FIGS. 19A, 19B and 19C, respectively, after forming a backside ILD layer 74. The backside ILD layer 74 is composed of one of the dielectric materials mentioned above for the first frontside ILD layer 26. The backside ILD layer 74 can be formed a deposition process including, but not limited to, CVD, PECVD or spin-on coating. A planarization process such as, for example, CMP can, but not necessarily always, follow the deposition process.

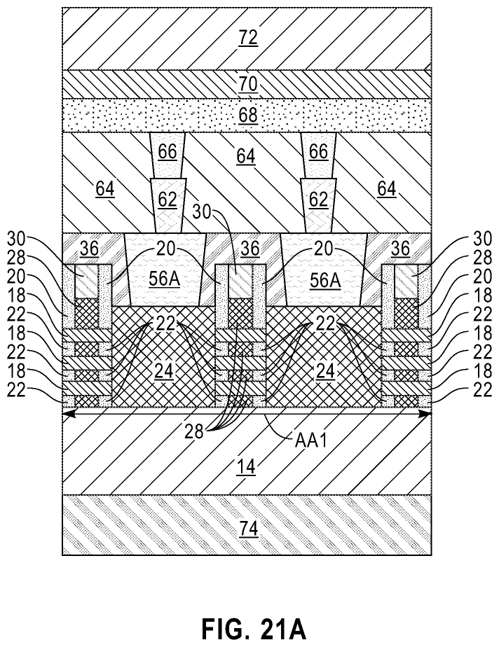

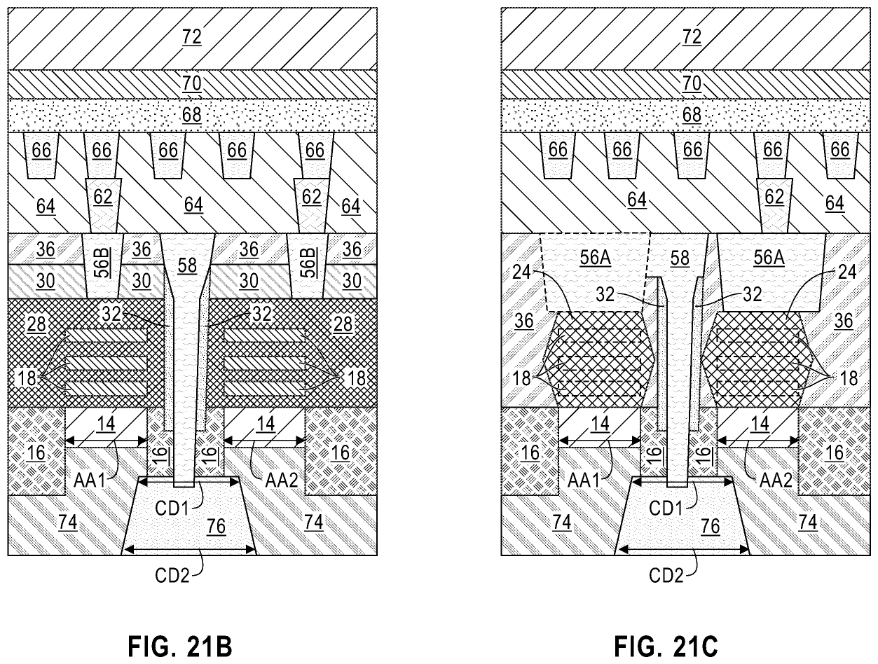

Referring now to FIGS. 21A, 21B and 21C, there are illustrated the exemplary structure shown in FIGS. 20A, 20B and 20C, respectively, after forming a backside power rail 76 in physically contact with a lower portion of the VBPR structure 58. The forming of the backside power rail 76 includes forming a backside power rail opening in the backside ILD layer 74 by lithography and etching. The etch reveals at least a bottommost surface of the VBPR structure 58. In some embodiments, the bottommost surface of the VBPR structure 58 that is physically exposed extends below a bottommost surface of the shallow trench isolation structure 16. In such an embodiment, the backside power rail 76 can contact the bottommost surface and a sidewall surface of the VBPR structure 58. A metallization process which includes filling the backside power rail opening with an electrically conductive power rail material, followed by planarization is the performed to provide the backside power rail 76. The filling can include any deposition process such as, for example, CVD, PECVD, ALD, or sputter. The electrically conductive power rail material includes, but is not limited to, W, Co, Ru, Al, Cu, Pt, Rh, or Pd. A thin metal adhesion layer, such as TiN, TaN, etc. can be also formed in the backside power rail opening prior to filling the backside power rail opening with the electrically conductive power rail material. The backside power rail 76 can have an upper portion having a first critical dimension, CD1, and a lower portion having a second critical dimension, CD2. In the present application, CD1 is less than CD2. In the present application (see, FIGS. 21B and 21C), the upper portion of the backside power rail 76 is closer to the VBPR structure 58 than the lower portion of the backside power rail 76.

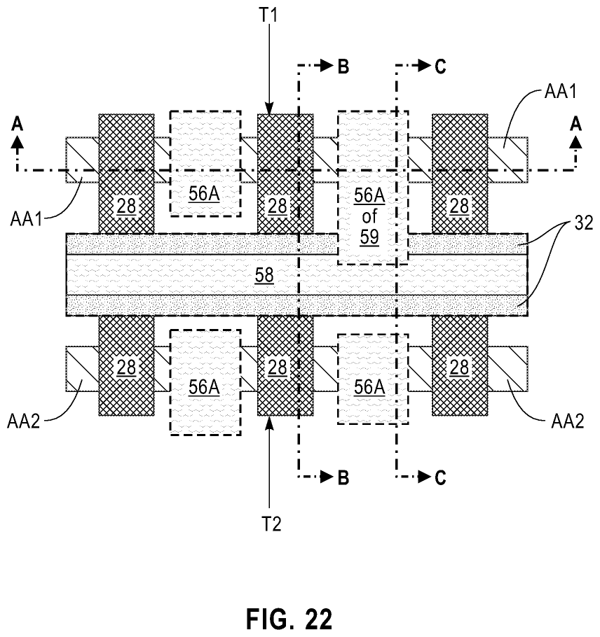

FIGS. 21A, 21B and 22C, and FIG. 22 illustrate a semiconductor device in accordance with an embodiment of the present application. The semiconductor device includes a first transistor (i.e., first nanosheet transistor T1) located on a frontside, and within first active area, AA1, of semiconductor device layer 14 and including gate structure 28 and source/drain regions 24. The semiconductor device further includes shallow trench isolation structure 16 located adjacent to AA1 of the semiconductor device layer 14, gate cap 30 located on the gate structure 28 of the first transistor, MOL dielectric layer 36 located on the gate cap 30 and embedding the source/drain regions 24 of the first transistor, backside power rail 76 located on a backside of the semiconductor device layer 16, and merged frontside source/drain contact/via-to-backside power rail (VBPR) structure 59 including frontside source/drain contact structure 56A merged with VBPR structure 58 in which the VBPR structure 58 is in electrical contact with the backside power rail 76 and the frontside source/drain contact structure 56A is in electrical contact with one of the source/drain regions 24 of the first transistor. In accordance with the present application, the VBPR structure 58 has an upper portion that is embedded in, and is in contact with, the MOL dielectric layer 36, a middle portion that is spaced apart from each of the gate cap 30, the gate structure 28 and the source/drain region 24 of the first transistor that is in electrical contact with the frontside source/drain contact structure 56A of the merged frontside source/drain contact/VBPR structure 59 by a gate cut dielectric spacer 32, and a lower portion that is surrounded by, and in direct contact with, the shallow trench isolation structure 16.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first transistor located on a frontside, and within a first active area, of a semiconductor device layer and comprising a gate structure and source/drain regions;
a shallow trench isolation structure located adjacent to the first active area of the semiconductor device layer;
a gate cap located on the gate structure of the first transistor;
a middle-of-the-line (MOL) dielectric layer located on the gate cap and embedding the source/drain regions of the first transistor;
a backside power rail located on a backside of the semiconductor device layer; and
a merged frontside source/drain contact/via-to-backside power rail (VBPR) structure comprising a frontside source/drain contact structure merged with a VBPR structure in which the VBPR structure is in electrical contact with the backside power rail and the frontside source/drain contact structure is in electrical contact with one of the source/drain regions of the first transistor, wherein the VBPR structure has an upper portion that is embedded in, and is in contact with, the MOL dielectric layer, a middle portion that is spaced apart from each of the gate cap, the gate structure and the source/drain region of the first transistor that is in electrical contact with the frontside source/drain contact structure by a gate cut dielectric spacer, and a lower portion that is surrounded by, and in direct contact with, the shallow trench isolation structure.

2. The semiconductor device of claim 1, wherein the upper portion of the VBPR structure has a first width, and the middle portion of the VBPR structure has a second width that is less than the first width.

3. The semiconductor device of claim 2, wherein the lower portion of the VBPR structure has a width that is substantially equal to the second width.

4. The semiconductor device of claim 1, wherein the gate cut dielectric spacer has a topmost surface that is substantially coplanar with a topmost surface of the gate cap.

5. The semiconductor device of claim 4, wherein the topmost surface of the gate cut dielectric spacer is located above a topmost surface of the source/drain region of the first transistor that is in electrical contact with the frontside source/drain contact structure.

6. The semiconductor device of claim 1, wherein the gate cut dielectric spacer has a bottommost surface that lands on a sub-surface of the shallow trench isolation structure.

7. The semiconductor device of claim 1, further comprising a non-shared frontside source/drain contact structure in electrical contact with the source/drain region of the first transistor that is not in electrical contact with the frontside source/drain contact structure of the merged frontside source/drain contact/VBPR structure.

8. The semiconductor device of claim 1, further comprising a frontside gate contact structure in contact with the gate structure of the first transistor.

9. The semiconductor device of claim 1, further comprising a frontside back-end-of-the-line (BEOL) structure located on the MOL dielectric layer.

10. The semiconductor device of claim 1, wherein the shallow trench isolation structure has a thickness that is greater than a thickness of the semiconductor device layer.

11. The semiconductor device of claim 1, wherein the backside power rail has an upper portion having a first critical dimension and a lower portion having a second critical dimension, wherein the second critical dimension is greater than the first critical dimension, and the upper portion of the backside power rail is closer to the VBPR structure than the lower portion of the backside power rail.

12. The semiconductor device of claim 1, wherein the VBPR structure extends beneath a bottommost surface of the shallow trench isolation structure.

13. The semiconductor device of claim 1, wherein the merged frontside source/drain contact/VBPR structure has a topmost surface that is substantially coplanar with a topmost surface of the MOL dielectric layer.

14. The semiconductor device of claim 1, wherein the gate cut dielectric spacer has an upper portion with a tapered profile.

15. The semiconductor device of claim 1, wherein the first transistor is a nanosheet transistor comprising a plurality of vertical stacked and spaced apart semiconductor channel material nanosheets.
